(19) United States
(12) Patent Application Publication
(10) Pub. No.: US 2014/0076611 A1
(43) Pub. Date: Mar. 20, 2014

(54) PRINTED CIRCUIT BOARD AND METHOD OF MANUFACTURING THE SAME

(71) Applicant: c/o SAMSUNG ELECTRO-MECHANICS CO., LTD., Suwon (KR)

(72) Inventors: Jin Won CHOI, Yongin (KR); Yon Ho YOU, Cheongju (KR)

(73) Assignee: c/o SAMSUNG ELECTRO-MECHANICS CO., LTD., Suwon (KR)

(21) Appl. No.: 14/022,821

(22) Filed: Sep. 10, 2013

(30) Foreign Application Priority Data
Sep. 17, 2012 (KR) 10-2012-0102738

(51) Int. Cl. H05K 1/02; H05K 3/00

(52) U.S. Cl. CPC H05K 1/0298; H05K 3/00
USPC 174/250; 228/176

(57) ABSTRACT

Disclosed herein is a method of manufacturing a printed circuit board, including: preparing a base substrate; disposing a mask having through-holes formed therein on one surface of the base substrate; inserting metal core balls into the through-holes of the mask, performing reflow treatment on the metal core balls, and removing the mask; and laminating an insulating layer on one surface of the base substrate.

### CROSS REFERENCE(S) TO RELATED APPLICATIONS

This application claims the benefit under 35 U.S.C. Section 119 of Korean Patent Application Serial No. 10-2012-0102738, entitled “Printed Circuit Board and Method of Manufacturing the Same” filed on Sep. 17, 2012, which is hereby incorporated by reference in its entirety into this application.

### BACKGROUND OF THE INVENTION

1. Technical Field

The present invention relates to a printed circuit board and a method of manufacturing the same, and more particularly, to a printed circuit board capable of improving reliability of vias by forming the vias having a uniform size, and a method of manufacturing the same.

2. Description of the Related Art

Recently, in accordance with an increase in a speed of a device, application of a flip chip has gradually increased. Particularly, a mounting connection scheme of a semiconductor chip such as a central processing unit (CPU) and a graphic calculating device rapidly calculating a high capacity of data has evolved from a wire bonding scheme using a wire to a flip chip bonding scheme of improving a connection resistance by connection using a solder.

Therefore, an increase in reliability and density of a printed circuit board on which semiconductor chips are mounted and connected to each other has been demanded. In addition, in accordance with the trend toward miniaturization, thinness, an increase in density, and packaging of a device, multi-layering for forming a plurality of circuit layers, fine patterning for making circuit patterns fine, miniaturization, and packaging of the printed circuit board have also been conducted.

An example of the printed circuit board as described above includes a single sided printed circuit board in which circuit patterns are formed only on one surface of an insulating substrate, a double sided printed circuit board in which circuit patterns are formed on both surfaces of the insulating substrate, and a multilayered board (MLB) wired in a multilayer.

In the multilayered board having the above-mentioned structure, fine circuit patterns on the respective layers include interlayer conduction vias formed at interlayer connection points. Here, in order to smoothly connect electrically upper layer circuit patterns and lower layer circuit patterns to each other through the vias, a matching degree between the vias and the circuit patterns should be excellent and reliability between the vias and the insulating layer should be excellent, at the time of forming the vias.

According to the related art, in order to form the via for interlayer conduction, an inner side circuit is formed, an insulating material is stacked, and a via hole is formed using a drill. Then, desmear treatment for removing the insulating material remaining on the bottom of the via hole formed using the drill to improve reliability of the via is performed. Next, an exposing process, a developing process, a plating process, a stripping process, a flash etching process are performed to form an outer layer circuit.

In the case of producing a product by performing the process using the drill as in the related art, a matching degree of the drill is decreased to cause eccentricity, such that a defect may occur. In addition, since an inner side of the via should be filled with a plating material, a process speed is low, and since a space occupied by an equipment for forming the via is very wide, a large cost is required. In addition, a defect such as a hole breakage, or the like, may occur at the time of evaluating reliability due to a fine void formed since plating between the insulating material and the via hole is not completely performed at the time of plating an outer layer.

### SUMMARY OF THE INVENTION

An object of the present invention is to provide a printed circuit board capable of increasing an interlayer matching degree, improving reliability by forming vias having the same size, and increasing production efficiency, and a method of manufacturing the same.

According to an exemplary embodiment of the present invention, there is provided a method of manufacturing a printed circuit board, including: preparing a base substrate; disposing a mask having through-holes formed therein on one surface of the base substrate; inserting metal core balls into the through-holes of the mask, performing reflow treatment on the metal core balls, and removing the mask; and laminating an insulating layer on one surface of the base substrate.

The method may further include, after the laminating of the insulating layer on one surface of the base substrate, desmear-treating a portion of the insulating layer.

In the desmear-treating of the portion of the insulating layer, the insulating layer may be desmear-treated so that one end of the metal core ball is formed as a plane.

The method according may further include, after the desmear-treating of the portion of the insulating layer, forming a circuit layer on one surface of the insulating layer.

In the laminating of the insulating layer on one surface of the base substrate, the insulating layer may be formed so that one end of the metal core ball is exposed.

The metal core ball may include a metal ball having a spherical shape and a solder part enclosing the metal ball.

The metal ball may be made of a metal or be formed by plating or coating a surface of a resin material with a metal.

The metal may be copper (Cu) or steel.

In the inserting of the metal core balls into the through-holes of the mask, the performing of the reflow treatment on the metal core balls, and the removing of the mask, a solder part of the metal core ball may be melted to thereby be connected to the circuit pattern.

According to another exemplary embodiment of the present invention, there is provided a printed circuit board including: a base substrate having circuit patterns formed thereon; metal core balls formed on the circuit patterns of the base substrate; and an insulating layer laminated so that one ends of the metal core balls are exposed.

The printed circuit board may further include a circuit layer formed on one surface of the insulating layer.

The metal core ball may include: a metal ball having a spherical shape; and a solder part formed between the metal ball and the circuit pattern to connect the metal ball to the circuit pattern.

The metal core ball may be formed so that one end thereof is formed as a plane.

### BRIEF DESCRIPTION OF THE DRAWINGS

FIG. 1 is a flow chart showing a method of manufacturing a printed circuit board according to an exemplary embodiment of the present invention;

FIGS. 2 to 10 are views sequentially showing processes of the method of manufacturing a printed circuit board according to the exemplary embodiment of the present invention; and

FIG. 11 is a cross-sectional view showing a printed circuit board according to another exemplary embodiment of the present invention.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

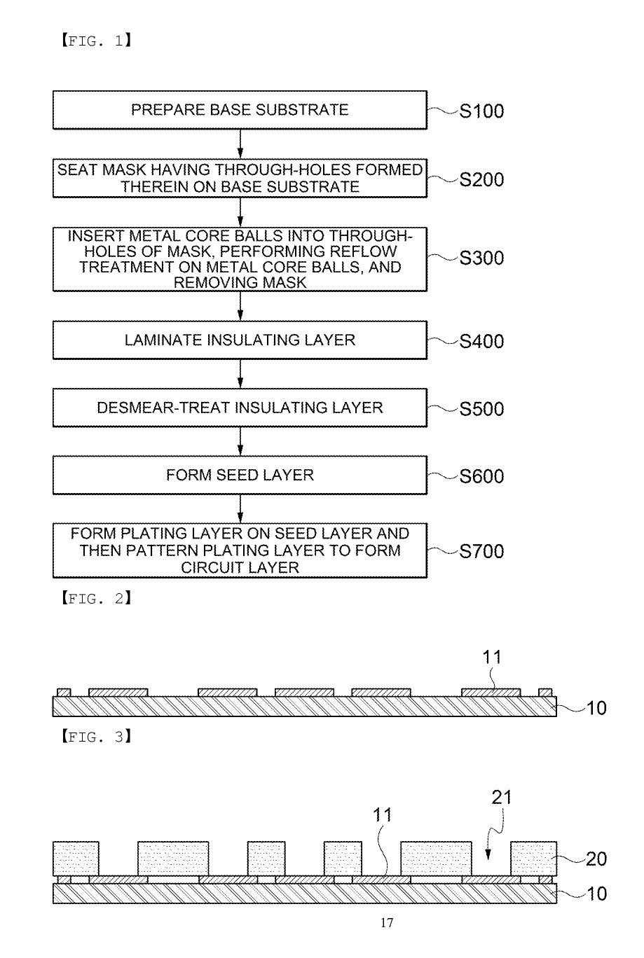

Hereinafter, a printed circuit board and a method of manufacturing the same according to exemplary embodiments of the present invention will be described in more detail with reference to FIGS. 1 to 10.

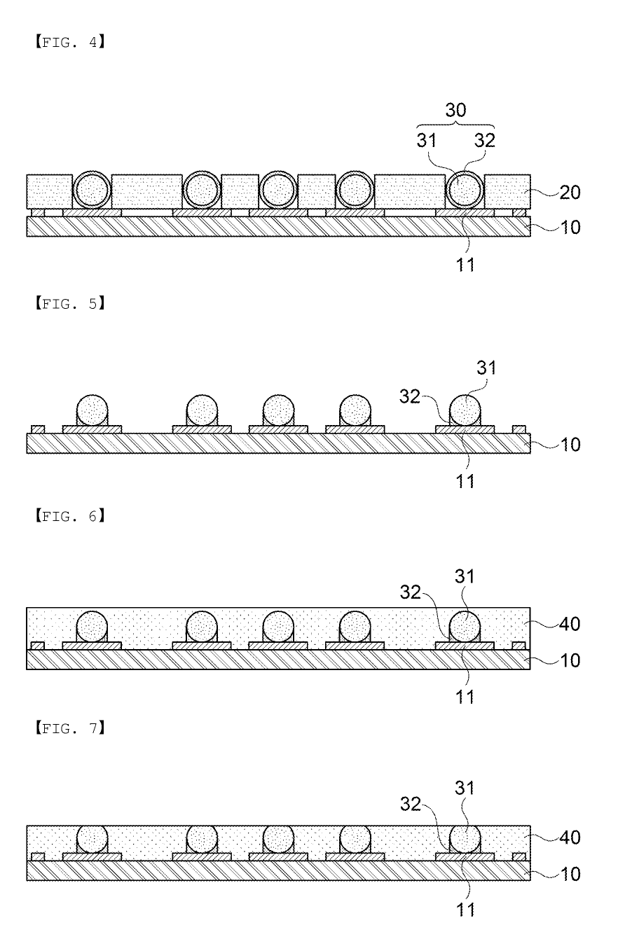

FIG. 1 is a flow chart showing a method of manufacturing a printed circuit board according to an exemplary embodiment of the present invention; and FIGS. 2 to 10 are sequentially showing processes of the method of manufacturing a printed circuit board according to the exemplary embodiment of the present invention.

Referring to FIGS. 2 to 10, a base substrate 10, circuit patterns 11, a mask 20, a metal core ball 30, an insulating layer 40, a seed layer 50, and a circuit layer 61 are shown.

In the method of manufacturing a printed circuit board according to the exemplary embodiment of the present invention, a step (S100) of preparing the base substrate 10 may be first performed.

The base substrate 10 is a raw material of the printed circuit board, and in the step of preparing the base substrate 10, the circuit patterns 11 may be formed on one surface of the base substrate 10.

Here, the base substrate 10, which is a plate shaped insulator, may be made of a copper clad laminate (CCL) in which a metal layer made of a metal material such as copper is formed on one surface or both surfaces or a glass fiber material impregnated with a thermosetting resin composition.

That is, the base substrate 10 may have the metal layer formed on one surface thereof, and the meal layer may be selectively etched to form the circuit patterns 11.

Next, a step (S200) of disposing the mask 20 having through-holes 21 formed therein on the base substrate 10 may be performed.

Here, the mask 20 may be made of a plate shaped metal material.

In addition, the mask 20 may have a plurality of through-holes 21 formed therein, wherein the through-hole 21 may be formed so as to correspond to the circuit patterns 11 at which vias are to be formed among the circuit patterns 11 formed on the base substrate 10.

That is, the mask 20 selectively exposes only the circuit patterns 11 at which the vias are to be formed and covers the circuit patterns 11 at which the vias are not to be formed.

Next, a step (S300) of inserting metal core balls 30 into the through-holes 21 of the mask 20, performing reflow treatment on the metal core balls 30, and removing the mask 20 may be performed.

Here, the metal core ball 30 may include a metal ball 31 having a spherical shape and a solder part 32 enclosing the metal ball 31.

Here, the metal ball 31 may be made of a material such as copper (Cu) or steel and be formed by plating or coating a surface of a resin material with a metal. Here, the resin material may be a synthetic resin material such as PP or PE.

In addition, the metal core ball 30 formed as described above may be inserted into the through-hole 21 of the mask 20. After the reflow treatment is performed on the metal core ball 30, the metal core ball 30 is connected to the circuit pattern 11, and the mask 20 is removed.

That is, since the solder part 32 of the metal core ball 30 formed on an outer peripheral surface of the metal ball 31 is melted at the time of reflow treatment to be filled between the metal ball 31 in the through-hole 21 and the circuit pattern 11, the circuit pattern 11 and the metal ball 31 are connected to each other by the solder part 32, such that the metal core ball 30 forms the via.

Then, a step (S400) of laminating the insulating layer 40 on an upper surface of the base substrate 10 may be performed. The present process is a build-up process for forming an outer layer.

Here, in the step of laminating the insulating layer 40, the insulating layer 40 in a semi-hardened state is put and pressed on the metal core ball 30 connected to the circuit pattern 11, such that the insulating layer 40 may be stacked and formed on the upper surface of the base substrate 10.

In addition, in the step of laminating the insulating layer 40, the insulating layer 40 is penetrated by the metal core ball 30, such that the metal core ball 30 may protrude upwardly of the insulating layer 40.

Then, a step (S500) of desmear-treating the insulating layer so that the metal core ball is exposed may be performed.

Here, the metal core ball 30 is exposed to the outside of the insulating layer 40 and the insulating layer 40 is desmear-treated so that a portion of an upper portion thereof is formed as a plane, such that an area at which the metal core ball 30 may contact the seed layer 50 formed on an upper surface of the insulating layer 40 is secured.

Next, a step (S600) of forming the seed layer 50 on the desmear-treated insulating layer 40 may be performed.

Here, the seed layer 50 may be made of a metal material such as copper (Cu) and be formed at a predetermined thickness by electroless plating.

Thereafter, a step (S700) of forming a plating layer 60 at a predetermined thickness on the seed layer 50 through electroplating and patterning the plating layer 60 to form the circuit layer 61 may be performed.

Here, the circuit layer 61 may be patterned by etching.

Further, although the case in which the circuit layer 61 is formed by the plating and etching processes has been described in the present embodiment, the present invention is not limited thereto. That is, the circuit layer 61 may be formed by a general method of forming a circuit pattern such as an inkjet printing method, a subtractive method, or the like.

Then, a process of disposing the mask 20 on the circuit layer 61, a process of inserting the metal core ball 30, performing reflow treatment on the metal core ball 30, and removing the mask 20, a process of laminating the insulating layer, a process of desmear-treating the insulating layer so that the metal core ball 30 is exposed, and a process of forming the circuit pattern are repeatedly performed, thereby making it possible to manufacture a multilayered board.

A printed circuit board according to the exemplary embodiment of the present invention will be described with reference to the accompanying drawings.

As shown in FIG. 10, the printed circuit board according to the exemplary embodiment of the present invention may be configured to include a base substrate 10, metal core balls 30, an insulating layer 40, and a circuit layer 61.

Here, the base substrate 10 is a raw material of the printed circuit board, and in the step of preparing the base substrate 10, the circuit patterns 11 may be formed on one surface of the base substrate 10.

Here, the base substrate 10, which is a plate shaped insulator, may be made of a copper clad laminate (CCL) in which a metal layer made of a metal material such as copper is formed on one surface or both surfaces, a glass fiber material impregnated with a thermosetting resin composition, or the like.

That is, the base substrate 10 may have the metal layer formed on one surface thereof, and the meal layer may be selectively etched to form the circuit patterns 11.

The metal core ball 30, which is formed on a selected circuit pattern 11 and is electrically connected to the selected circuit pattern 11, may include a metal ball 31 and a solder part 32 formed between the metal ball 31 and the circuit pattern 11 to electrically connect the metal ball 31 and the circuit pattern 11 to each other.

That is, the metal core ball 30 may be connected to the circuit pattern 11 to serve as a via electrically connecting the circuit pattern 11 to a circuit layer 61 to be described below.

Here, the metal ball 31 may be made of a material such as copper (Cu) or steel and be formed by plating or coating a surface of a resin material with a metal. Here, the resin material may be a synthetic resin material such as PP or PE.

In addition, an upper portion of the metal ball 31 is formed as a plane, thereby making it possible to secure a contact area between the metal ball 31 and the circuit layer 61.

The insulating layer 40, which is to form the circuit layer 61 stacked on the base substrate 10, may be made of a thermosetting resin such as an epoxy resin, a thermoplastic resin such as polyimide, or the like.

Here, the insulating layer 40 may be formed so that an upper end of the metal ball 31 is exposed.

The circuit layer 61, which is a circuit pattern formed on the insulating layer 40, may be formed so as to be connected to the exposed upper end of the metal ball 31 and be formed by a general process of forming a circuit pattern.

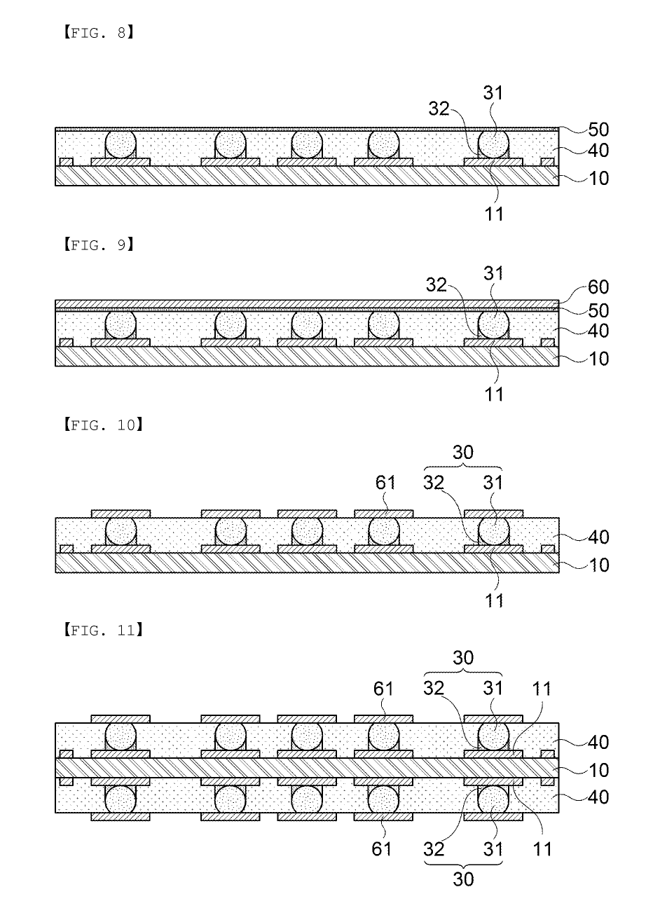

In addition, although a single sided printed circuit board having circuit patterns formed only on an upper surface of the base substrate 10 has been described by way of example in the present embodiment, double sided printed circuit board having circuit patterns formed on both of the upper and lower surfaces of the base substrate 10 as shown in FIG. 11 may also be used.

Therefore, in the printed circuit board and the method of manufacturing the same according to the exemplary embodiment of the present invention, a process of inserting the metal core balls into the through-holes formed in the mask to connect the metal core balls to the circuit patterns is used instead of a drill process at the time of forming the vias, thereby making it possible to increase a matching degree of the vias. In addition, since a plating process is not required, a manufacturing time and a manufacturing cost may be decreased. In addition, the metal core balls having the same size are used to form the vias having the same size, thereby making it possible to improve reliability for electrical connection.

As set forth above, in the printed circuit board and the method of manufacturing the same according to the exemplary embodiment of the present invention, a process of forming the metal core balls serving as the vias in the circuit pattern is performed instead of a drill process at the time of forming the vias, thereby making it possible to increase a matching degree of the vias. In addition, since a plating process is not required, a manufacturing time and a manufacturing cost may be decreased. In addition, the metal core balls having the same size are used to form the vias having the same size, thereby making it possible to improve reliability for electrical connection.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A method of manufacturing a printed circuit board, comprising:
preparing a base substrate;
disposing a mask having through-holes formed therein on one surface of the base substrate;
inserting metal core balls into the through-holes of the mask, performing reflow treatment on the metal core balls, and removing the mask; and
laminating an insulating layer on one surface of the base substrate.

2. The method according to claim 1, further comprising, after the laminating of the insulating layer on one surface of the base substrate, desmear-treating a portion of the insulating layer.

3. The method according to claim 2, wherein in the desmear-treating of the portion of the insulating layer, the insulating layer is desmear-treated so that one end of the metal core ball is formed as a plane.

4. The method according to claim 2, further comprising, after the desmear-treating of the portion of the insulating layer, forming a circuit layer on one surface of the insulating layer.

5. The method according to claim 1, wherein in the laminating of the insulating layer on one surface of the base substrate, the insulating layer is formed so that one end of the metal core ball is exposed.

6. The method according to claim 1, wherein the metal core ball includes a metal ball having a spherical shape and a solder part enclosing the metal ball.

7. The method according to claim 6, wherein the metal ball is made of a metal or is formed by plating or coating a surface of a resin material with a metal.

8. The method according to claim 7, wherein the metal is copper (Cu) or steel.

9. The method according to claim 1, wherein in the inserting of the metal core balls into the through-holes of the mask, the performing of the reflow treatment on the metal core balls, and the removing of the mask, a solder part of the metal core ball is melted to thereby be connected to the circuit pattern.

10. A printed circuit board comprising:
a base substrate having circuit patterns formed thereon;
metal core balls formed on the circuit patterns of the base substrate; and
an insulating layer laminated so that one ends of the metal core balls are exposed.

11. The printed circuit board according to claim 10, further comprising a circuit layer formed on one surface of the insulating layer.

12. The printed circuit board according to claim 10, wherein the metal core ball includes:
a metal ball having a spherical shape; and
a solder part formed between the metal ball and the circuit pattern to connect the metal ball to the circuit pattern.

13. The printed circuit board according to claim 10, wherein the metal core ball is formed so that one end thereof is formed as a plane.
